(19) United States
(12) Patent Application Publication
(10) Pub. No.: US 2024/0297148 A1
(43) Pub. Date: Sep. 5, 2024

(54) POWER MODULE WITH IMPROVED SEMICONDUCTOR DIE ARRANGEMENT FOR ACTIVE CLAMPING

(71) Applicant: Littelfuse Semiconductor (Wuxi) Co., Ltd., Wuxi (CN)

(72) Inventor: Martin Schulz, Erwitte (DE)

(73) Assignee: Littelfuse Semiconductor (Wuxi) Co., Ltd., Wuxi (CN)

(21) Appl. No.: 18/591,815

(22) Filed: Feb. 29, 2024

(30) Foreign Application Priority Data
Mar. 3, 2023 (CN) 202310198579.6

(51) Int. Cl. H01L 25/065; H01L 23/00; H01L 23/15

(52) U.S. Cl. CPC H01L 25/0652; H01L 23/15; H01L 24/32; H01L 24/48; H01L 24/73; H01L 2224/32145; H01L 2224/32245; H01L 2224/4813; H01L 2224/48137; H01L 2224/73265; H01L 2924/01029; H01L 2924/12; H01L 2924/13055; H01L 2924/13091

(57) ABSTRACT

A power semiconductor device arrangement. The power semiconductor device arrangement may include a substrate that has a ceramic body, a top metal layer, disposed on a top surface of the ceramic body, and a bottom metal layer, disposed on a bottom surface of the ceramic body, opposite the top surface. The power semiconductor device may further include a power transistor die, comprising a power transistor device, where the power transistor die is disposed over the top surface of the substrate. The power semiconductor device may include a diode die assembly, comprising a set of diodes, and being disposed over the top surface of the substrate, adjacent to the power transistor die. The power semiconductor device may include a wire bond connector, having a first end, affixed to an upper surface of the diode die assembly, and a second end, affixed to an upper surface of the power transistor die.

### CROSS-REFERENCE TO CORRESPONDING APPLICATIONS

This application claims the benefit of priority to, Chinese Patent Application No. 202310198579.6, filed Mar. 3, 2023, entitled “POWER MODULE WITH IMPROVED SEMICONDUCTOR DIE ARRANGEMENT FOR ACTIVE CLAMPING,” which application is incorporated herein by reference in its entirety.

### FIELD

Embodiments relate to the field of semiconductor devices, and in particular, power module semiconductor die architecture. Discussion of Related Art.

Modern power semiconductor devices like silicon-controlled rectifiers (“SCRs”), power transistors, insulated gate-bipolar transistors (“IGBTs”), metal-oxide-semiconductor field effect transistors (“MOSFETs”), bipolar power rectifiers, power regulators, or combinations thereof, may be assembled in packages that include substrates that support semiconductor die containing the aforementioned semiconductor devices. These substrates may be contained in insulating housing that provides various connections to outside components. Such a housing/substrate/semiconductor die assembly may be referred to as a power semiconductor device module (also referred to herein as “power modules”). The role of such a substrate in power semiconductor device modules may be to provide interconnections from semiconductor die components to other components in a power semiconductor device module, as well as for thermal management of heat generated by the semiconductor die. Compared to materials and techniques used in lower power electronics, the substrates of a power semiconductor device module are designed to carry higher currents and provide a higher voltage isolation (up to several thousand volts), as well as to operate over a wide temperature range (up to 150 C or 200° C., for example).

Direct bonded copper (DBC) substrates are commonly used in power modules, because of the very good thermal conductivity of DBC modules. These modules are composed of a ceramic material having a body in the shape of a plate or disc, such as aluminum oxide or aluminum nitride, where a sheet of is copper bonded to one or both sides of the ceramic body by a high-temperature oxidation process. The copper and substrate may be heated in a special process where an alloy or compound forms that bonds successfully both to copper and the ceramic used as the substrate. In some arrangements, the top copper layer may be preformed prior to firing or chemically etched using printed circuit board technology to form an electrical circuit, while the bottom copper layer is usually kept as a blanket layer. The substrate may further be attached to a heat sink by soldering or otherwise connecting a metal heat sink to the bottom copper layer.

In a variant of the DBC approach, direct bonded aluminum substrates may employ a ceramic body having a layer of aluminum bonded to a top surface and bottom surface.

In known power modules, one or more substrates, such as DBC substrates, may be provided within a given power module, where each DBC substrate includes multiple semiconductor die that are attached to a top surface of the given DBC substrate. In known configurations, a power transistor device, such as an insulated gate bipolar transistor (IGBT) or power metal oxide semiconductor field effect transistor (MOSFET), may be embodied within a given semiconductor die, where the single device occupies substantially the whole semiconductor die. Said differently, a given semiconductor die may include just one device, such as one IGBT device or one MOSFET.

Often, in a known power module, a power transistor device will be accompanied by a freewheeling diode device that is embodied in a separate semiconductor die. These freewheeling diodes are mandatory to handle inductive currents. Again, in a power module, multiple diode die may be arranged on one or more substrates, where a given freewheeling diode die is electrically connected to one or more power transistor die. In known power modules, the architecture for connections between power transistor die and freewheeling diode die is as compact as possible, due to the nature of the electrical arrangement of the diode(s) and transistor die elements, and the DBC substrates. As a result, the distance between a freewheeling diode die and a power transistor die is the smallest possible, thus not inherently offering space to add protective measures using known, off-the-shelf-components. Protection in the form of overvoltage limiting arrangements, often a transient voltage suppression (TVS) diode, is added externally to the DBC substrate that supports the power transistor die and freewheeling diode, leading to unduly long connections which in turn add parasitic elements that negatively influence the protective functionality in speed, accuracy or effectiveness.

In view of the above, the present embodiments of the present disclosure are provided.

### BRIEF SUMMARY

In one embodiment, a power semiconductor device arrangement is provided. The power semiconductor device arrangement may include a substrate that has a ceramic body, a top metal layer, disposed on a top surface of the ceramic body, and a bottom metal layer, disposed on a bottom surface of the ceramic body, opposite the top surface. The power semiconductor device may further include a power transistor die, comprising a power transistor device, where the power transistor die is disposed over the top surface of the substrate. The power semiconductor device may include a diode die assembly, comprising a set of diodes, and being disposed over the top surface of the substrate, adjacent to the power transistor die. The power semiconductor device may include a wire bond connector, having a first end, affixed to an upper surface of the diode die assembly, and a second end, affixed to an upper surface of the power transistor die.

In another embodiment, a power semiconductor device module may include a housing, and a power semiconductor device arrangement that includes a substrate. The substrate may include a ceramic body, a top metal layer, disposed on a top surface of the ceramic body, and a bottom metal layer, disposed on a bottom surface of the ceramic body, opposite the top surface. The power semiconductor device module may also include a power transistor die, comprising a power transistor device, the power transistor die being disposed over the top surface of the substrate. The power semiconductor device module may further include a diode die assembly, comprising a set of diodes, the diode die assembly disposed over the top surface of the substrate, adjacent to the power transistor die. The power semiconductor device module may additionally include a wire bond connector, having a first end, affixed to an upper surface of the diode die assembly, and a second end, affixed to an upper surface of the power transistor die.

### BRIEF DESCRIPTION OF THE DRAWINGS

FIG. 1A shows a side view of a power semiconductor device arrangement, according to embodiments of the disclosure;

FIG. 1B shows a top view of the power semiconductor device arrangement of FIG. 1A, according to embodiments of the disclosure;

FIG. 1C shows an electrical circuit representation of a power semiconductor device assembly, in accordance with embodiments of the disclosure;

FIG. 1D shows details of a variant of the semiconductor device arrangement of FIG. 1A, according to embodiments of the disclosure;

FIG. 1E shows a power semiconductor device module, according to embodiments of the disclosure;

FIG. 1F shows a reference power semiconductor device arrangement;

FIG. 2A shows a side view of a power semiconductor device arrangement of FIG. 1A, according to embodiments of the disclosure; and

FIG. 2B shows an electrical circuit representation of a variant of the power semiconductor device arrangement of FIG. 1A.

### DESCRIPTION OF EMBODIMENTS

The present embodiments will now be described more fully hereinafter with reference to the accompanying drawings, in which exemplary embodiments are shown. The embodiments are not to be construed as limited to the embodiments set forth herein. Rather, these embodiments are provided so that this disclosure will be thorough and complete, and will fully convey their scope to those skilled in the art. In the drawings, like numbers refer to like elements throughout.

In the following description and/or claims, the terms “on,” “overlying,” “disposed on” and “over” may be used in the following description and claims. “On,” “overlying,” “disposed on” and “over” may be used to indicate that two or more elements are in direct physical contact with one another. Also, the term “on,”, “overlying,” “disposed on,” and “over”, may mean that two or more elements are not in direct contact with one another. For example, “over” may mean that one element is above another element while not contacting one another and may have another element or elements in between the two elements. Furthermore, the term “and/or” may mean “and”, it may mean “or”, it may mean “exclusive-or”, it may mean “one”, it may mean “some, but not all”, it may mean “neither”, and/or it may mean “both”, although the scope of claimed subject matter is not limited in this respect.

The present embodiments, as describe herein below, are designed to improve the protection capabilities given by so-called active clamping. This improvement is achieved by providing an arrangement of voltage-limiting devices such as diodes, that are locally electrically connected between a gate-contact and input power terminal of a semiconductor switch (Collector in the case of an IGBT or Drain in the case of MOSFET). This arrangement will feature the shortest possible connections, minimized parasitic elements and integration consuming the lowest possible area.

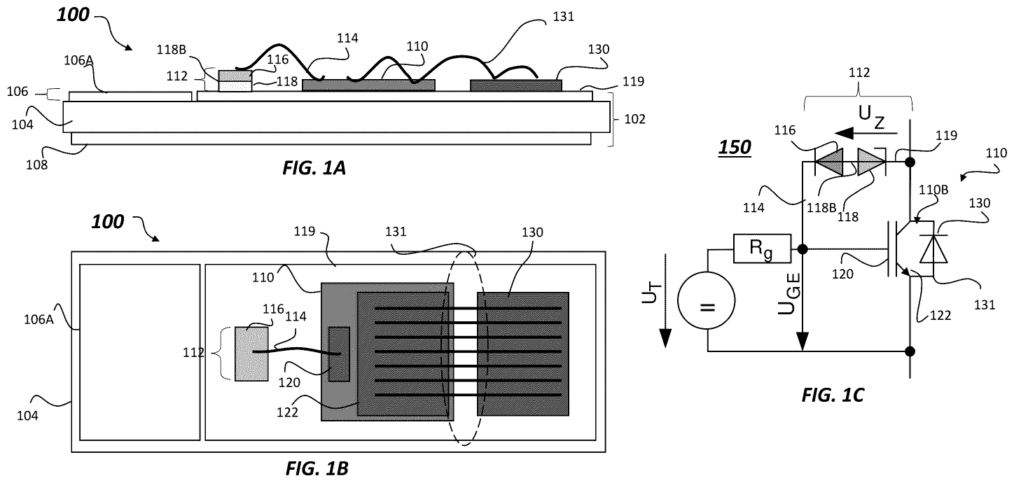

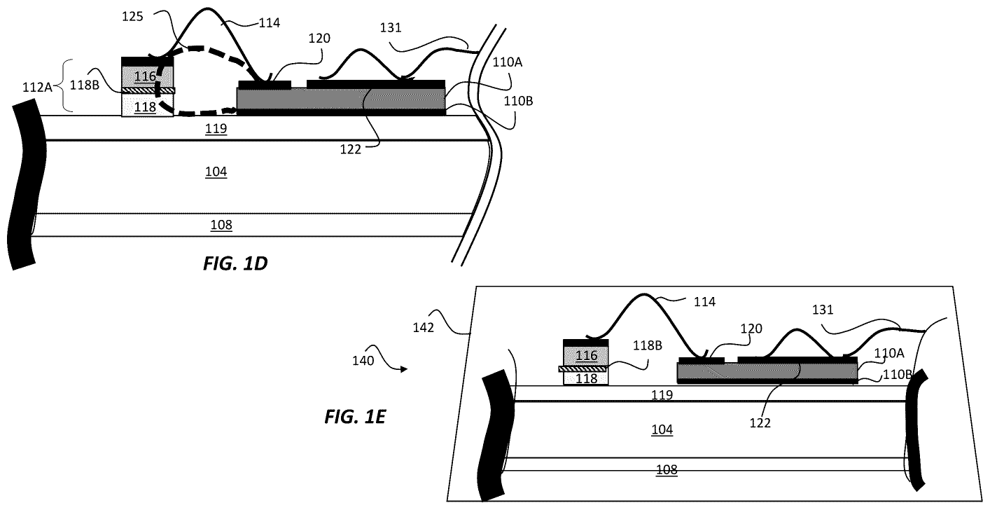

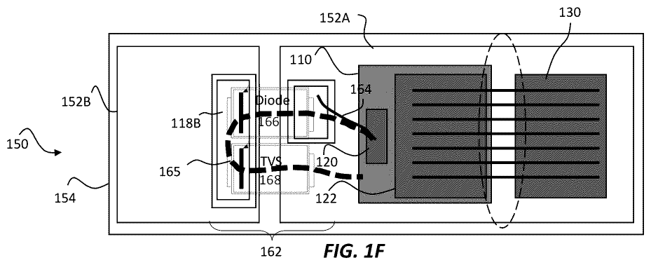

FIG. 1A shows a side view of a power semiconductor device arrangement 100, according to embodiments of the disclosure. FIG. 1B shows a top view of the power semiconductor device arrangement 100 FIG. 1C. shows an electrical circuit representation of a variant of the power semiconductor device arrangement 100. FIG. 1D shows details of a variant of the power semiconductor device arrangement 100, according to embodiments of the disclosure. FIG. 1E shows a power semiconductor device module 140, including the power semiconductor device arrangement 100 and a housing 142, according to embodiments of the disclosure.

The power semiconductor device arrangement 100 may be included in a power semiconductor device module, as known in the art, where various components are omitted for clarity, including housing, various connectors, and so forth.

The power semiconductor device arrangement 100 includes a substrate 102, a power transistor die 110, and diode die assembly 112, where the diode die assembly 112 is connected to the power transistor die by a wire bond connector 114. The wire bond connector 114 may include one or more wires, for example. The substrate 102 may include a ceramic body 104, a top metal layer 106, disposed on a top surface of the ceramic body 104, and a bottom metal layer 108, disposed on a bottom surface of the ceramic body 104, opposite the top surface.

The substrate 102 may be a direct bonded copper (DBC) substrate, wherein the top metal layer 106 is a copper layer, according to some embodiments. In other embodiments, the substrate 102 may be a direct bonded aluminum (DBA) substrate, where the top metal layer 106 is aluminum.

The power transistor die 110 may include a power transistor device, such as a MOSFET, IGBT, and so forth. In some examples, the power transistor die 110 may include a single power transistor device. The diode die assembly 112 generally may include a plurality of diode devices, or diodes.

In various embodiments, the top metal layer 106 may be divided into a plurality of metal portions that are isolated from one another. In the embodiment of FIG. 1A, the top metal layer 106 is divided into a metal portion 106A and a metal portion 119. In these embodiments, the power transistor die 110 and diode die assembly 112 are affixed to the same metal portion, that is, to the metal portion 119 of top metal layer 106. Note that the metal portion 106A may act as a landing pad for further connections, such as bond wires, to form more complex structures than a single switch.

In the illustration of FIG. 1A and FIG. 1D, a first diode 118 (such as a first diode die where the first diode 118 is embodied in a single semiconductor die) is shown, affixed to the top metal portion 119. The first diode 118 may be any suitable diode, having the function to prevent current from a gate driver being diverted into the collector of an IGBT in the power transistor die, for example. A second diode 116 (such as a second diode die where the second diode 116 is embodied in a single semiconductor die) is disposed above the first diode 118, where the second diode 116 is connected to the wire bond connector 114. In one embodiment, the first diode 118 may be a Zener- or TVS-diode die, while the second diode 116 represents any suitable diode die providing the blocking capabilities needed.

In other embodiments, the second diode 116 may be used to prevent current diversion into the collector of the IGBT while the first diode 118 represents a TVS diode.

As further depicted at FIG. 1A, the power semiconductor device arrangement 100 includes a freewheeling diode 130, disposed on the metal portion 119, connected to the power transistor die 110 via bond wire assembly 131.

FIG. 1C represents a suitable schematic comprising a TVS-diode (second diode 116) in combination with a reverse-protecting diode (first diode 118). As seen in FIG. 1A (see also FIGS. 1D, 1E), according to embodiments of the disclosure, the connection between the protective arrangement (diode die assembly 112) and the power transistor die can be reduced to a single, short bond-wire (wire bond connector 114), a direct soldering of a die-to-die attachment (118B), and placement of the diode die assembly directly on the metal portion 119 that is shared with the semiconductor switch (power transistor die 110).

Note that in various embodiments, as suggested in FIG. 1C, the diode (second diode 116) and the Zener diode (first diode 118) are electrically coupled in series to one another in an anode-to-anode configuration, wherein a first end of the wire bond connector 114 is connected to a cathode of the TVS diode die. In other embodiments, a TVS diode die and the first diode die are electrically coupled in series to one another in a cathode-to-cathode configuration, wherein the first end of the wire bond connector is connected to a cathode of the TVS diode die.

Note that in various embodiments, the second diode 116 may represent a plurality of diodes, generally of the same type, arranged in a first configuration, such as anodes all arranged in a first direction, while the first diode 118 may also represent a second plurality of diodes, generally of the same type, arranged in a second configuration, such as cathodes all arranged in the first direction.

As further shown in FIG. 1B, and also in the side view of FIG. 1D, a gate electrode 120 may be provided on the top surface of the power transistor die 110, where the gate electrode 120 is arranged toward an edge of the power transistor die 110 that is nearest to the diode die assembly 112. In this configuration, the second end of the wire bond connector 114 is affixed to the gate electrode 120 as shown in FIG. 1B and FIG. 1D in particular (note that in FIG. 1D and FIG. 1E some components may be omitted for clarity, such as freewheeling diode 130, etc.). This arrangement allows the length of the wire bond connector 114 to be advantageously reduced, due to the direct connection of the second diode 116 to the gate electrode 120, and the proximity of the diode die assembly 112 to the power transistor die 110. In some embodiments, the wire length of the wire bond connector 114 may be reduced to, for example, 20 mm or below. Moreover, the electrical connection between a diode die assembly and the gate of a power transistor device is simplified, in that, the cathode of the TVS diode is presented on an exposed surface, allowing for a simple wiring connection to be made to a power transistor device, without intermediate components.

Note that the power transistor die 110 may be formed with a main terminal electrode 110B, disposed on a bottom surface of the power transistor die 110, and bonded to the top metal layer 106, such as the metal portion 119 of the substrate 102. Additionally, a second main terminal electrode 122 may be disposed on the top surface of the power transistor die 110.

In summary, the power device arrangement of the present embodiments provides a power device function having an active clamping that is implemented with fewer components and less real estate in a module as compared to known power semiconductor modules and the use of arrangements added to power modules externally. An advantage afforded by the present embodiments may be further understood with respect a reference power semiconductor arrangement, shown in FIG. 1F

In FIG. 1F, a power semiconductor arrangement 150 includes a power transistor die 110 and freewheeling diode 130, arranged on a substrate 154, with a first portion 152A and second portion 152B of a top metal layer. In this arrangement, a diode assembly 162, which assembly may supply similar function to the diode die assembly 112, is provided. The diode assembly 162 includes a diode 166 (connected to power transistor die 110 using wire bond connector 164) and TVS diode 168, which components are arranged in planar fashion as in known power surface mount device (SMD) semiconductor packages. The diode 166 and TVS diode 168 span between the first portion 152A and second portion 152B.

Integration of the diode assembly 162, together with the power transistor die 110 and freewheeling diode 130 into a SMD package may be impractical due to the large real estate occupied by these semiconductor components. Particularly when series-connection is needed to achieve the blocking voltage needed, the problem is amplified. Furthermore, this configuration also requires the need to reserve DCB-area for solder contacts, including isolating trenches. With at least two components, this configuration requires an area of approximately 1 cm×1 cm of space on a substrate. That is, 100 mm² more space is needed to accommodate the diode assembly 162, equivalent to a large IGBT die. Note that such an assembly as in FIG. 1F may be suitable for applications to provide 600 V clamping. In the case of 1200 V IGBTs, at least two diodes arranged in series would be required, meaning additional area on a substrate would be needed to accommodate the diodes in an SMD configuration. In contrast, the diode die assembly 112 just requires an area of <10 mm² and no need for isolating trenches. Moreover, adding a third die in a stacked configuration of the embodiment of the diode die assembly 112 does not consume additional area on the substrate 102.

In addition the embodiment of FIG. 1A-1D provides enhanced performance with respect to the reference arrangement of FIG. 1F. In FIG. 1D, there is shown a commutation loop 125 generated by the diode die assembly 112A and power transistor die 110. In FIG. 1F a commutation loop 165 is shown for the power semiconductor arrangement 150. In this example, the commutation loop 165 has a much larger enclosed area than the commutation loop 125, meaning the arrangement of FIG. 1D will have improved speed and accuracy of protection as compared to the arrangement of FIG. 1F.

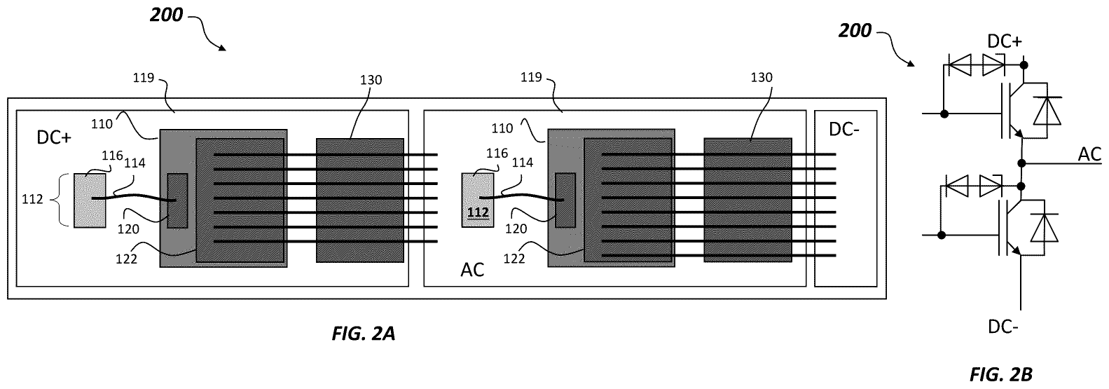

FIG. 2A shows a side view of a power semiconductor device arrangement 200, according to embodiments of the disclosure. FIG. 2B shows an electrical circuit representation of a variant of the power semiconductor device arrangement 100. In this arrangement, two IGBTs with added freewheeling diodes form a so-called half-bridge. Each of the switches needs individual protection, given by the embodiments described with respect to FIGS. 1A-1E that employ just one power transistor die (110). The half-bridge, also called an inverter stage, can connect either DC+ or DC− to the AC-terminal and by implementing proper control patterns allows generating an AC-voltage from a DC-source. The technique is the well-established state-of-the-art today.

While the present embodiments have been disclosed with reference to certain embodiments, numerous modifications, alterations and changes to the described embodiments are possible while not departing from the sphere and scope of the present disclosure, as defined in the appended claims. Accordingly, the present embodiments are not to be limited to the described embodiments and may have the full scope defined by the language of the following claims, and equivalents thereof.

What is claimed is:

1. A power semiconductor device arrangement, comprising:
a substrate, the substrate comprising:
a ceramic body;
a top metal layer, disposed on a top surface of the ceramic body; and
a bottom metal layer, disposed on a bottom surface of the ceramic body, opposite the top surface;
a power transistor die, comprising a power transistor device, the power transistor die being disposed over the top surface of the substrate;
a diode die assembly, comprising a set of diodes, the diode die assembly disposed over the top surface of the substrate, adjacent to the power transistor die; and
a wire bond connector, having a first end, affixed to an upper surface of the diode die assembly, and a second end, affixed to an upper surface of the power transistor die.

2. The power semiconductor device arrangement of claim 1, the power transistor die comprising an insulated gate bipolar transistor (IGBT) or a metal oxide semiconductor field effect transistor (MOSFET).

3. The power semiconductor device arrangement of claim 1, the diode die assembly comprising:
a first diode die, bonded to the top metal layer of the substrate; and
a transient voltage suppression (TVS) diode die, disposed over the first diode die.

4. The power semiconductor device arrangement of claim 3, wherein a top surface of the TVS diode die is connected to the first end of the wire bond connector.

5. The power semiconductor device arrangement of claim 3, wherein the TVS diode die and the first diode die are electrically coupled in series to one another in an anode-to-anode configuration, wherein the first end of the wire bond connector is connected to a cathode of the TVS diode die.

6. The power semiconductor device arrangement of claim 3, wherein the TVS diode die and the first diode die are electrically coupled in series to one another in a cathode-to-cathode configuration, wherein the first end of the wire bond connector is connected to a cathode of the TVS diode die.

7. The power semiconductor device arrangement of claim 1, wherein the second end of the wire bond connector is affixed to a gate electrode, the gate electrode being disposed on an upper surface of the power transistor die.

8. The power semiconductor device arrangement of claim 7, wherein the power transistor die comprises a main terminal electrode, disposed on a bottom surface of the power transistor die, and wherein the main terminal electrode is bonded to the top metal layer of the substrate.

9. The power semiconductor device arrangement of claim 1, wherein the substrate comprises a direct bonded copper (DBC) substrate, wherein the top metal layer is a copper layer.

10. The power semiconductor device arrangement of claim 1, the top metal layer comprising a first portion, wherein the power transistor die and the diode die assembly are disposed on the first portion of the top metal layer.

11. The power semiconductor device arrangement of claim 10, further comprising a freewheeling diode, wherein a cathode end of the freewheeling diode is disposed on the first portion of the top metal layer, and wherein an anode end of the freewheeling diode is directly connected to the power semiconductor die.

12. A power semiconductor device module, comprising:
a housing; and
a power semiconductor device arrangement, comprising:
a substrate, the substrate comprising:
a ceramic body;
a top metal layer, disposed on a top surface of the ceramic body; and
a bottom metal layer, disposed on a bottom surface of the ceramic body, opposite the top surface;
a power transistor die, comprising a power transistor device, the power transistor die being disposed over the top surface of the substrate;
a diode die assembly, comprising a set of diodes, the diode die assembly disposed over the top surface of the substrate, adjacent to the power transistor die; and
a wire bond connector, having a first end, affixed to an upper surface of the diode die assembly, and a second end, affixed to an upper surface of the power transistor die.

13. The power semiconductor device module of claim 12, the power transistor die comprising an insulated gate bipolar transistor (IGBT) or a metal oxide semiconductor field effect transistor (MOSFET).

14. The power semiconductor device module of claim 12, the diode die assembly comprising:
a first diode die, bonded to the top metal layer of the substrate; and
a transient voltage suppression (TVS) diode die, disposed over the first diode die.

15. The power semiconductor device module of claim 14, wherein a top surface of the TVS diode die is connected to the first end of the wire bond connector.

16. The power semiconductor device module of claim 14, wherein the TVS diode die and the first diode die are electrically coupled in series to one another in an anode-to-anode configuration, wherein the first end of the wire bond connector is connected to a cathode of the TVS diode die.

17. The power semiconductor device module of claim 14, wherein the TVS diode die and the first diode die are electrically coupled in series to one another in a cathode-to-cathode configuration, wherein the first end of the wire bond connector is connected to a cathode of the TVS diode die.

18. The power semiconductor device module of claim 12, wherein the second end of the wire bond connector is affixed to a gate electrode, the gate electrode being disposed on an upper surface of the power transistor die.

19. The power semiconductor device module of claim 16, wherein the power transistor die comprises a main terminal electrode, disposed on a bottom surface of the power transistor die, and wherein the main terminal electrode is bonded to the top metal layer of the substrate.

20. The power semiconductor device arrangement of claim 12, the top metal layer comprising a first portion, wherein the power transistor die and the diode die assembly are disposed on the first portion of the top metal layer.
